(19) United States
(12) Patent Application Publication
(10) Pub. No.: US 2023/0036433 A1
(43) Pub. Date: Feb. 2, 2023

(54) ELECTRONIC DEVICE

(71) Applicant: InnoLux Corporation, Miao-Li County (TW)

(72) Inventors: Huai-Ping HUANG, Miao-Li County (TW); Rui-An YU, Miao-Li County (TW); Chang-Chiang CHENG, Miao-Li County (TW); Chia-Hao TSAI, Miao-Li County (TW); Chih-Lung LIN, Miao-Li County (TW); Jian-Min LEU, Miao-Li County (TW)

(21) Appl. No.: 17/814,436

(22) Filed: Jul. 22, 2022

(30) Foreign Application Priority Data
Jul. 29, 2021 (CN) 202110862155.6

(51) Int. Cl. H01L 27/12

(52) U.S. Cl. CPC H01L 27/124; H01L 27/1248

(57) ABSTRACT

An electronic device includes a substrate including an active area and a peripheral area adjacent to the active area; a plurality of spacers disposed in the active area and including a first spacer and a second spacer; a plurality of signal lines disposed on the substrate and extending along a first direction; a plurality of gate lines disposed on the substrate and extending along a second direction; and a gate driving unit disposed in the active area and including a receiving switch element and a buffer switch element, wherein the receiving switch element is disposed corresponding to the first spacer and receives an input signal through one of the signal lines, and the buffer switch element is disposed corresponding to the second spacer and is electrically connected to the receiving switch element, wherein the buffer switch element outputs a scan signal to one of the gate lines.

### CROSS REFERENCE TO RELATED APPLICATION

This application claims the benefits of the Chinese Patent Application Serial Number 202110862155.6, filed on Jul. 29, 2021, the subject matter of which is incorporated herein by reference.

### BACKGROUND

### 1. Field of the Disclosure

The present disclosure relates to an electronic device and, more particularly, to an electronic device in which a gate driving unit is disposed in an active region.

### 2. Description of Related Art

With the advancement of science and technology, all electronic products are developed toward the trend of compact and lightweight. In order to pursue a more refined edge visual sense, various manufacturers are also committed to the design of narrow border to meet the needs of consumers.

Therefore, there is still a need to develop an electronic device to achieve the effect of narrow border.

### SUMMARY

In view of this, the present disclosure provides an electronic device, especially an electronic device in which the gate driving unit is disposed in the active region, so as to achieve the effect of narrow border.

To achieve the above object, the present disclosure provides an electronic device, which comprises: a substrate including an active area and a peripheral area adjacent to the active area; a plurality of spacers disposed in the active area and including a first spacer and a second spacer; a plurality of signal lines disposed on the substrate and extending along a first direction; a plurality of gate lines disposed on the substrate and extending along a second direction, wherein the first direction is different from the second direction; and a gate driving unit disposed in the active area and including a receiving switch element and a buffer switch element, wherein the receiving switch element is disposed corresponding to the first spacer and receives an input signal through one of the signal lines, and the buffer switch element is disposed corresponding to the second spacer and is electrically connected to the receiving switch element, wherein the buffer switch element outputs a scan signal to one of the gate lines.

Other novel features of the disclosure will become more apparent from the following detailed description when taken in conjunction with the accompanying drawings.

### BRIEF DESCRIPTION OF THE DRAWINGS

FIG. 1 is a schematic circuit diagram of a gate driving unit according to an embodiment of the present disclosure;

FIG. 2 is a schematic diagram of the electronic device according to an embodiment of the present disclosure;

FIG. 3A and FIG. 3B are top views of part of an active area of the electronic device according to an embodiment of the present disclosure;

FIG. 4 is a top view of part of an active area of the electronic device according to an embodiment of the present disclosure;

FIG. 5 is a top view of part of an active area of the electronic device according to an embodiment of the present disclosure;

FIG. 6 is a schematic diagram of part of an active area of the electronic device according to an embodiment of the present disclosure;

FIG. 7A is a schematic diagram of part of an active area of the electronic device according to an embodiment of the disclosure;

FIG. 7B is a schematic cross-sectional view of FIG. 7A taken along line A-A′;

FIGS. 8A and 8B are schematic cross-sectional views of part of an active area of the electronic device according to an embodiment of the present disclosure;

FIG. 9 is a top view of part of an active area of the electronic device according to an embodiment of the present disclosure;

FIG. 10 is a top view of part of an active area of the electronic device according to an embodiment of the present disclosure; and

FIG. 11 is a schematic diagram of an active area of the electronic device according to an embodiment of the present disclosure.

### DETAILED DESCRIPTION OF EMBODIMENT

The following provides different embodiments of the present disclosure. These embodiments are used to illustrate the technical content of the present disclosure, rather than to limit the claims of the present disclosure. A feature of one embodiment can be applied to other embodiments through suitable modification, substitution, combination, and separation.

It should be noted that, in the specification and claims, unless otherwise specified, having “one” component is not limited to having a single said component, but one or more said components may be provided. In addition, in the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. A “first” component and a “second” component may appear together in the same component, or separately in different components. The existence of a component with a larger ordinal number does not necessarily mean the existence of another component with a smaller ordinal number.

In the entire specification and the appended claims of the present disclosure, certain words are used to refer to specific components. Those skilled in the art should understand that electronic device manufacturers may refer to the same components by different names. The present disclosure does not intend to distinguish those components with the same function but different names. In the claims and the following description, the words “comprise” “include” and “have” are open type language, and thus they should be interpreted as meaning “including but not limited to . . . ”. Therefore, when the terms “comprise”, “include” and/or “have” are used in the description of the present disclosure, they specify the existence of corresponding features, regions, steps, operations and/or components, but do not exclude the existence of one or more corresponding features, regions, steps, operations and/or components.

The terms “about”, “equal to”, “same”, “substantially” or “approximately” are generally to be interpreted as within 20% of a given value, or as within 10%, 5%, 3%, 2%, 1%, or 0.5% of the given value.

Unless otherwise defined, all terms (including technical and scientific terms) used here have the same meanings as commonly understood by those skilled in the art of the present disclosure. It is understandable that these teams, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side.

When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

In addition, if a value is between a first value and a second value, the value can be the first value, the second value, or another value between the first value and the second value.

It should be noted that the technical solutions provided by the different embodiments below can be replaced, combined or used in combination, so as to constitute another embodiment without violating the spirit of the present disclosure.

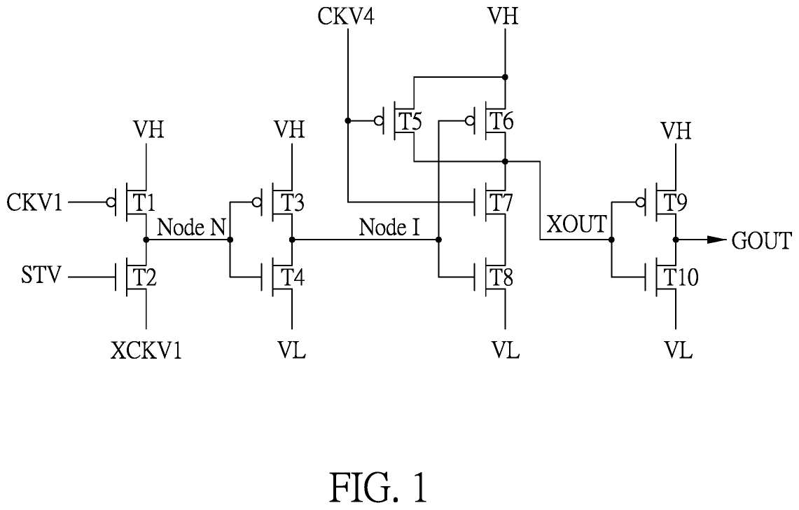

FIG. 1 is a schematic circuit diagram of a gate driving unit according to an embodiment of the disclosure. As shown in FIG. 1, the gate driving unit may include a plurality of switch elements (T1 to T10). The plurality of switch elements (T1 to T10) are electrically connected to each other by wires to transmit signal from the start signal input end STV to the signal output end GOUT, and the plurality of switch elements (T1 to T10) can be electrically connected with a plurality of signal lines (for example, XCKV1, VH, VL, CKV4 shown in FIG. 1) to transmit signal from a controller (not shown) to each switch element. In the schematic diagram of FIG. 1, the gate driving unit includes ten switch elements (T1 to T10), but the present disclosure is not limited thereto. In other embodiments of the present disclosure, the gate driving unit may include twenty, thirty or more switch elements, or less than ten switch elements according to requirements and designs.

In addition, the plurality of switch elements may form a vertical shift register (VSR), a buffer, etc., and have corresponding functions. For example, the switch elements T1, T2, T3 and T4 may form a vertical shift register, and the switch elements T9 and T10 may form a buffer, but the present disclosure is not limited thereto.

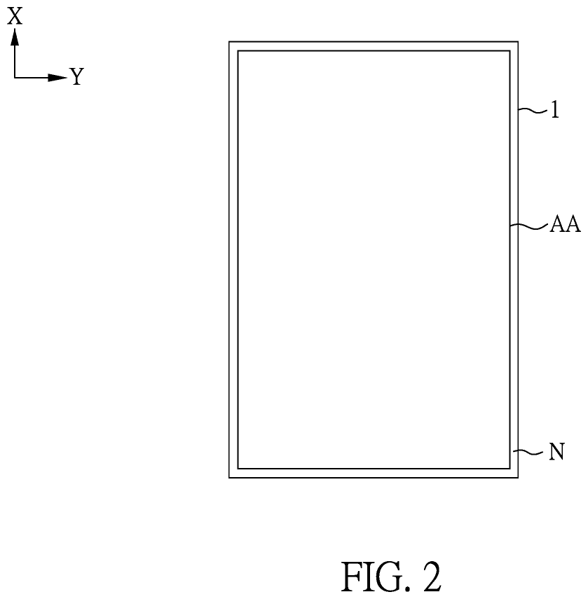

FIG. 2 is a schematic diagram of the electronic device according to an embodiment of the present disclosure.

As shown in FIG. 2, the electronic device of the present disclosure includes a substrate 1 and the substrate 1 includes an active area AA and a peripheral area N, wherein the peripheral area N is adjacent to the active area AA. In the present disclosure, the gate driving unit (not shown) can be disposed in the active area AA, so that the electronic device can be provided with the effect of narrow border.

The active area of the electronic device of the present disclosure will be described in detail below.

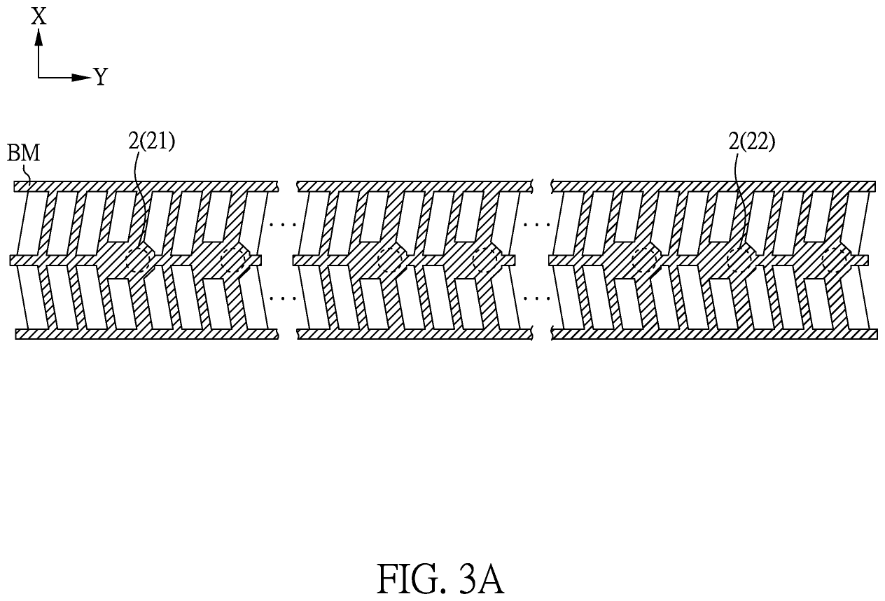

FIG. 3A and FIG. 3B are top views of part of an active area of the electronic device according to an embodiment of the present disclosure, wherein FIG. 3A and FIG. 3B are the same schematic diagrams but, for the convenience of description, the light shielding layer of FIG. 3A is omitted in FIG. 3B. In addition, the circuit diagram of FIG. 3B is such as shown in FIG. 1 and, for convenience of description, some switch elements are omitted in FIG. 3B.

As shown in FIG. 2, FIGS. 3A and 3B, the electronic device of the present disclosure includes: a plurality of spacers 2 disposed in the active area AA and including a first spacer 21 and a second spacer 22; a plurality of signal lines 3 disposed on the substrate 1 and extending along a first direction X; a plurality of gate lines 4 disposed on the substrate 1 and extending along a second direction Y, wherein the first directions X is different from the second direction Y; and a gate driving unit GD disposed in the active area AA and including a receiving switch element T2 and a buffer switch element T10. The receiving switch element T2 is disposed corresponding to the first spacer 21 and receives an input signal the signal XCKV1 in FIG. 1) from one of the signal lines 3. The buffer switch element T10 is disposed corresponding to the second spacer 22 and is electrically connected to the receiving switch element 12, wherein the buffer switch element T10 outputs a scan signal to one of the gate lines 4. By arranging the gate driving unit GD in the active area AA, the present disclosure can reduce the area occupied by the gate driving unit GD and its wiring disposed in the peripheral area N as in the prior art, so as to achieve the effect of narrow border.

As shown in FIG. 2 and FIG. 3B, the electronic device of the present disclosure further includes a plurality of data lines 5 disposed on the substrate 1 and extending along the first direction X. The data lines 5 and the gate lines 4 intersect to define a plurality of sub-pixel units P.

In the present disclosure, the gate driving unit GD includes a plurality of switch elements T1 to T10. In one embodiment of the present disclosure, the receiving switch element 12 can be used for receiving the input signal inputted from the signal line 3, and the buffer switch element T10 can be used for outputting the scan signal to the gate line 4. In addition, as shown in FIG. 3B, the gate driving unit GD may further include other switch elements (for example, T1, T6, T7 and T9 in FIG. 3B) corresponding to the switch elements shown in FIG. 1, and these switch elements may be disposed corresponding to the same spacer or different spacers. At least some of the other switch elements can be electrically connected to the receiving switch element T2 and/or the buffer switch element T10. However, it should be noted that the positions and electrical connections of the switch elements shown in FIG. 3B are only an example, and the present disclosure is not limited thereto.

As shown in FIG. 3A and FIG. 3B, the electronic device of the present disclosure further includes a light shielding layer BM disposed on the substrate 1, and the light shielding layer BM can cover a plurality of spacers 2, a plurality of signal lines 3, and a plurality of gate lines 4 and/or the plurality of data lines 5 so as to reduce the situation that the display quality of the electronic device is degraded due to light leakage or reflected light. More specifically, the light shielding layer BM can be disposed above the plurality of spacers 2, the plurality of signal lines 3, the plurality of gate lines 4 and/or the plurality of data lines 5. Therefore, in the normal direction of the substrate 1, the light shielding layer BM may at least partially overlap with the plurality of spacers 2, the plurality of signal lines 3, the plurality of gate lines 4 and/or the plurality of data lines 5, and the spacers 2, the signal lines 3, the gate lines 4 and the data lines 5 may be disposed between the light shielding layer BM and the substrate 1.

In the present disclosure, a plurality of spacers 2 may be randomly disposed in the active area AA to provide the electronic device with a support effect. Since the switch elements (for example, the receiving switch element 12 and the buffer switch element T10) can be disposed corresponding to the spacer 2 (for example, adjacent to the spacer 2 or at least partially overlapping with the spacer 2), the switch elements can share the light shielding layer BM disposed above the spacer 2, so as to achieve a shielding effect without additionally disposing other light shielding layers BM for the switch element, thereby increasing the aperture ratio of the electronic device.

In addition, since there may be a plurality of sub-pixel units P between two adjacent spacers 2, the display quality is not severely affected. In addition, in the present disclosure, a sub-spacer (not shown) with a height slightly smaller than the spacer 2 may also be disposed between two adjacent spacers 2 so as to enhance the support effect. Although the switch elements are not disposed corresponding to the sub-spacers in this embodiment, the present disclosure is not limited thereto. In some embodiments, the switch elements may be disposed corresponding to the sub-spacers.

Herein, the materials of the signal line 3, the gate line 4 and the data line 5 may include metal, metal oxide, or a combination thereof. The metal can be, for example, gold, silver, copper, aluminum, molybdenum, titanium, chromium, alloy thereof, or a combination thereof. The metal oxide can be, for example, indium tin oxide (ITO), indium zinc oxide (IZO), or a combination thereof. However, the present disclosure is not limited thereto. In addition, the signal line 3, the gate line 4 and the data line 5 may be prepared using the same or different materials. The light shielding layer BM is a black matrix layer, and the material of the light shielding layer BM may include a black metal layer (such as molybdenum oxide, copper oxide, other suitable materials or a combination thereof), a black ink layer, a black resin layer, an anti-reflection material, or a light absorbing material, but the present disclosure is not limited thereto.

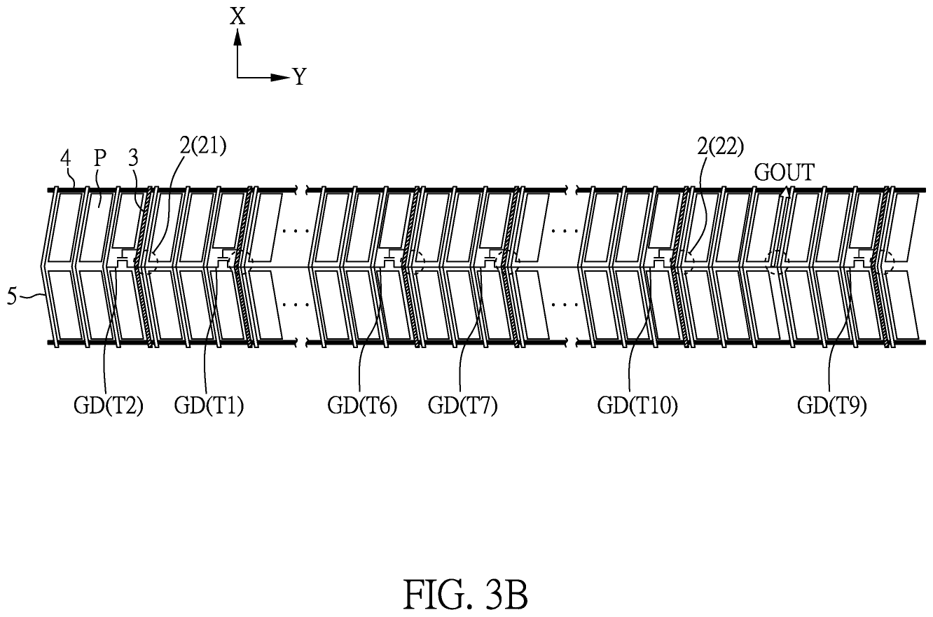

FIG. 4 is a top view of part of an active area of the electronic device according to an embodiment of the present disclosure. FIG. 4 is similar to FIG. 3A and FIG. 3B but, for the convenience of description, part of the light shielding layer is omitted in FIG. 4.

As shown in FIG. 4, in the present disclosure, the gate lines 4 and the data lines 5 intersect to define a plurality of sub-pixel units, and the plurality of sub-pixel units may include a first sub-pixel unit P11, a second sub-pixel unit P12 and a third sub-pixel unit P13. The second sub-pixel unit P12 is disposed between the first sub-pixel unit P11 and the third sub-pixel unit P13. The first sub-pixel unit P11 may be a red sub-pixel unit R, the second sub-pixel unit P12 may be a green sub-pixel unit G, and the third sub-pixel unit P13 may be a blue sub-pixel unit B, but the present disclosure is not limited thereto.

In the present disclosure, when the volume of the switch element is relatively large, the switch element (such as the receiving switch element T2 or the buffer switch element T10) in the gate driving unit GD can be disposed adjacent to, for example, the blue sub-pixel unit B, so as to reduce the aperture ratio of the blue sub-pixel unit B, and make the aperture ratio of the blue sub-pixel unit B different from the aperture ratio of the green sub-pixel unit G. More specifically, The ratio of the aperture ratio of the blue sub-pixel unit B to the green sub-pixel unit G may be between 70% and 99% (70%≤the ratio of aperture ratios ≤99%), for example, between 70% and 90% (70%≤the ratio of aperture ratios ≤90%) but the present disclosure is not limited thereto. Since human eyes are less sensitive to blue, appropriately reducing the aperture ratio of the blue sub-pixel unit B has little influence on the display effect. It should be noted that the switch elements may also be disposed adjacent to sub-pixels of other colors (for example, red or green) under the condition of having little influence on the display effect,

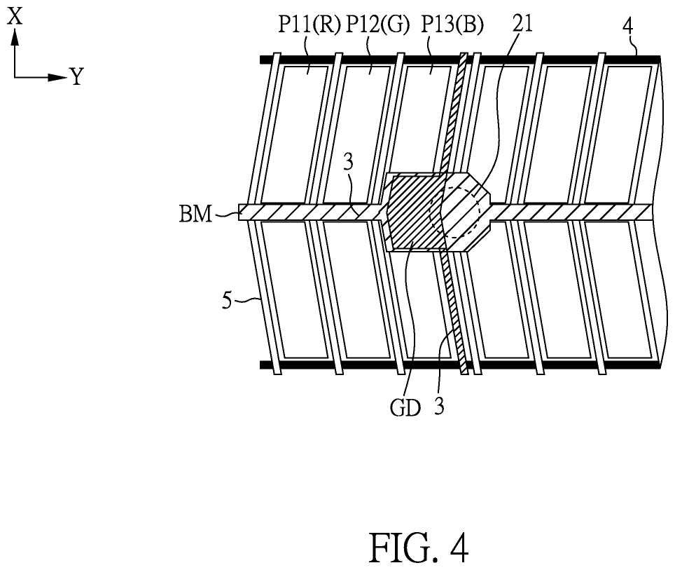

FIG. 5 is a top view of part of an active area of the electronic device according to an embodiment of the present disclosure, wherein FIG. 5 is similar to FIG. 3A and FIG. 3B, except for the following differences. In addition, for the convenience of description, part of the light shielding layer is omitted in FIG. 5.

As shown in FIG. 5, the buffer switch element T10 of the present disclosure may include a first sub-switch element T10-1 and a second sub-switch element T10-2, wherein the first sub-switch element T10-1 and the second sub-switch element T10-2 are electrically connected to each other in parallel (as shown by the dotted line). Since the volume of the buffer switch element T10 may be relatively large, the buffer switch element T10 can be disassembled into a plurality of sub-switch elements without causing a severe influence to the display effect, and the plurality of sub-switch elements are connected in parallel with each other to maintain the function of the buffer switch element. In this embodiment, the buffer switch element T10 is disassembled into two sub-switch elements, but the present disclosure is not limited thereto. In other embodiments of the present disclosure, the buffer switch element T10 can be disassembled into three, four or more sub-switch elements, and the sub-switch elements are connected in parallel with each other.

In this embodiment, the buffer switch element T10 is disassembled into a plurality of sub-switch elements, but the present disclosure is not limited thereto. Similarly, when another switch element is larger in size, this switch element can also be disassembled into a plurality of sub-switch elements to achieve the same effect. For example, the switch element T1 (as shown in FIG. 3B) may include a first sub-switch element and a second sub-switch element, wherein the first sub-switch element and the second sub-switch element are electrically connected to each other in parallel. In addition, in other embodiments of the present disclosure, the switch element T1 can be disassembled into three, four or more sub-switch elements, and the sub-switch elements are connected in parallel with each other. Similar to the buffer switch element T10 or the switch element T1, the other switch elements T2 to T9 each can also be disassembled into two or more sub-switch elements connected in parallel. It should be noted that, when the switch element is disassembled into a plurality of sub-switch elements, the sub-switch elements may be disposed respectively corresponding to the same or different spacers.

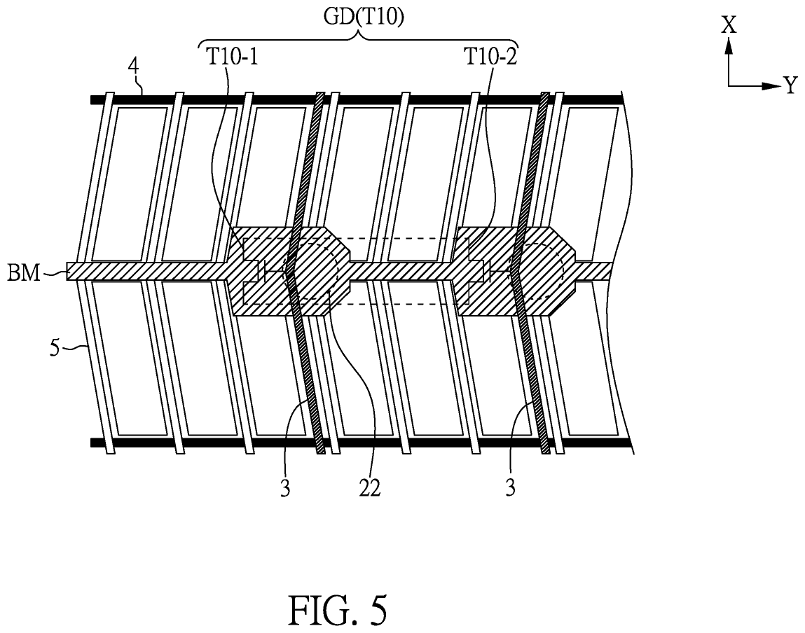

FIG. 6 is a schematic diagram of part of an active area of the electronic device according to an embodiment of the present disclosure, wherein FIG. 6 is similar to FIG. 3A and FIG. 3B except for the following differences. In addition, for convenience of description, the light shielding layer is omitted in FIG. 6.

Please refer to FIG. 3A, FIG. 3B and FIG. 6. When using the same metal layer to form the signal line 3 and the data line 5, since the signal line 3 and the data line 5 need to be electrically insulated from each other, the signal line 3 and the data line 5 will be separated by a distance and, moreover, in order to shield the signal line 3 and the data line 5 at the same time, as shown in FIG. 3A, the light shielding layer BM disposed above the signal line 3 has a larger width. In the embodiment shown in FIG. 6, the signal line 3 and the data line 5 may be formed respectively using different metal layers, and the signal line 3 may be disposed on the data line 5 (and in some embodiments, the data line 5 can be disposed on the signal line 3). More specifically, in the normal direction of the substrate 1, the signal line 3 may at least partially overlap the data line 5. Therefore, the light shielding layer BM may be provided with the effect of shielding the signal line 3 and the data line 5 at the same time without increasing or with only slightly increasing the width of the light shielding layer BM disposed above the signal lines 3.

In addition, when the electronic device of the present disclosure is applied to a touch device, it may further include a touch signal line 6 disposed on the substrate 1. Herein, the touch signal line 6 may be prepared using a material similar to or different from that of the signal line 3. When the same metal layer as the signal line 3 is used to prepare the touch signal line 6, the process steps can be further simplified. Therefore, as shown in FIG. 6, the touch signal line 6 can be disposed on the data line 5. More specifically, in the normal direction of the substrate 1, the touch signal line 6 may at least partially overlap the data line 5. In this way, the light shielding layer BM can achieve the shielding effect without increasing or with only slightly increasing the width of the light shielding layer BM.

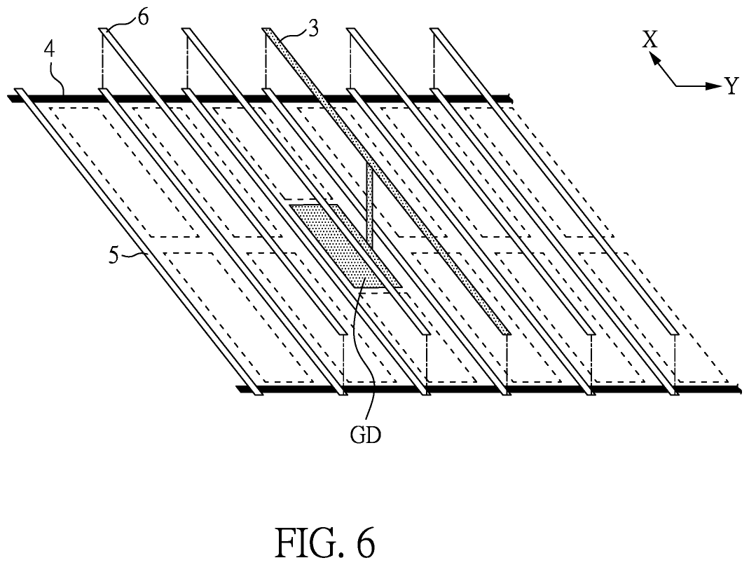

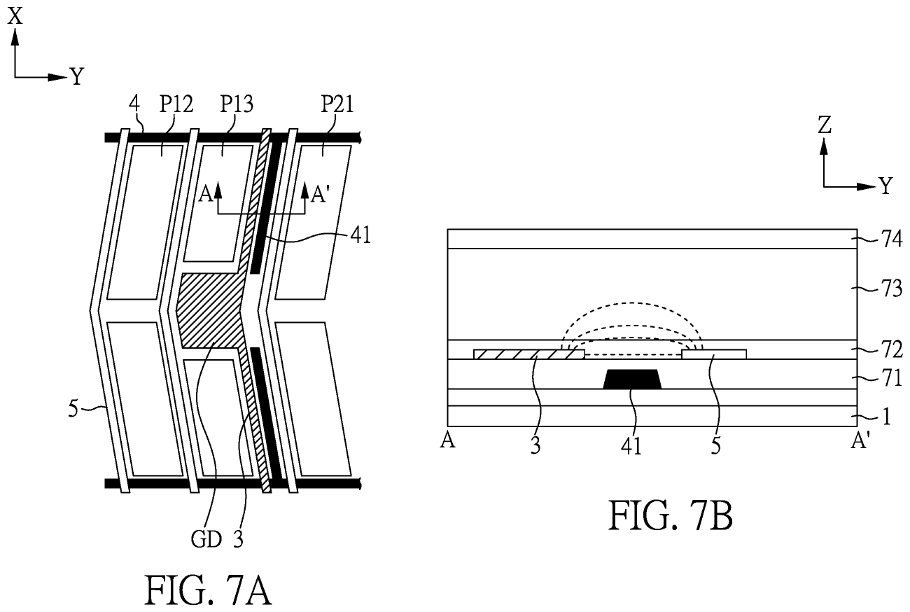

FIG. 7A is a schematic diagram of part of an active area of the electronic device according to an embodiment of the present disclosure. FIG. 7B is a schematic cross-sectional view of FIG. 7A taken along the line A-A′.

As shown in FIG. 7A and FIG. 7B when the same metal layer is used to form the signal line 3 and the data line 5, since the signal line 3 and the data line 5 need to be electrically insulated from each other, the signal line and the data lire 5 will be separated by a distance to reduce the situation of voltage transmission error caused by capacitive coupling effect between the signal line 3 and the data line 5. However, at this time, a wider light shielding layer BM must be used for shielding, which may affect the display effect. Therefore, in an embodiment of the present disclosure, the electronic device may further include a first line segment 41 disposed on the substrate 1. For example, as shown in FIG. 7A the first line segment 41 may be electrically connected to the gate line 4 and extend along the first direction X, the signal line 3 is disposed to be adjacent to one of the data lines 5, and the first line segment 41 is disposed between the signal line 3 and data line 5. As shown in FIG. 7B, the first line segment 41 may be in a different layer from the signal line 3 and the data line 5 (disposed, for example, at a layer lower than the signal line 3 and the data line 5), and is electrically insulated from the signal line 3 and the data line 5, respectively. Therefore, the electronic device of the present disclosure may further include an insulating layer disposed between the first line segment 41 and the signal line 3 and between the first line segment 41 and the data line 5. The first line segment 41 may be at the same voltage level as the gate line 4. With the arrangement of the first line segment 41, part of the power lines between the signal line 3 and the data line 5 can be shielded, so as to improve the capacitive coupling effect between the signal line 3 and the data line 5.

In the present disclosure, the insulating layer may be a single layer structure or a multi-layer structure. As shown in FIG. 7B, the insulating layer is a first insulating layer 71 disposed on the substrate 1 and located between the first line segment 41 and the signal line 3 and between the first line segment 41 and the data line 5. Herein, the material of the first insulating layer 71 may include silicon nitride, silicon oxide, silicon oxynitride, aluminum oxide, polymer, photoresist, or a mixture thereof, but the present disclosure is not limited thereto.

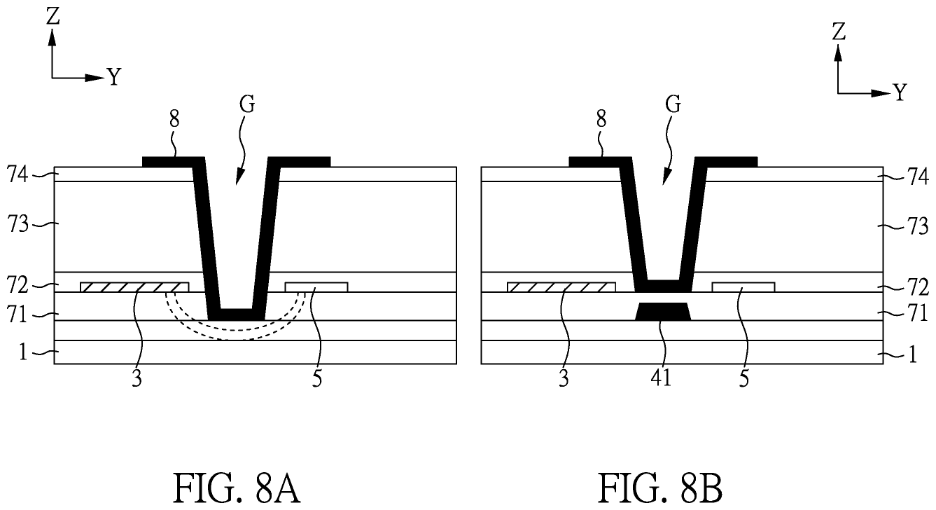

FIG. 8A and FIG. 8B are schematic cross-sectional views of part of an active area of the electronic device according to an embodiment of the present disclosure. FIGS. 8A and SB are similar to FIGS. 7A and 7B except for the following differences.

As shown in FIG. 8A, in the present disclosure, the electronic device may further include an insulating layer disposed on the signal line 3 and the data line 5, and the groove G may be disposed between two adjacent signal line 3 and the data line 5. In addition, a conductive layer 8 can be disposed in the groove G. The conductive layer 8 extends along the first direction X and has a voltage level as same as the first line segment 41. With the groove G and the conductive layer 8 disposed therein, part of the power lines between the signal line 3 and the data line 5 can be shielded, so as to improve the capacitive coupling effect between the signal line 3 and the data line 5.

In the present disclosure, the insulating layer may be a single layer structure or a multi-layer structure. When the insulating layer is a multi-layer structure, as shown in FIG. 8A, the insulating layer may further include a second insulating layer 72, a third insulating layer 73 and a fourth insulating layer 74, and the groove G may be formed in the second insulating layer 7, the third insulating layer 73 and the fourth insulating layer 74. The conductive layer 8 can be disposed on the fourth insulating layer 74 and extend in the groove G to shield part of the power lines between the signal line 3 and the data line 5. In addition, as shown in FIG. 8A, in this embodiment, the range of the groove G can be extended to the first insulating layer 71 to further improve the capacitive coupling effect between the signal line 3 and the data line 5.

Herein, the materials of the second insulating layer 72, the third insulating layer 73 and the fourth insulating layer 74 may be similar to those of the first insulating layer 71, and thus a detailed description is deemed unnecessary. In addition, the first insulating layer 71, the second insulating layer 72, the third insulating layer 73 and the fourth insulating layer 74 may be made of the same or different materials. The material of the conductive layer 8 may include transparent conductive electrodes, such as indium tin oxide (ITO), indium zinc oxide (ILO), indium gallium zinc oxide (IGZO) or a combination thereof, but the present disclosure is not limited thereto. In some embodiments, the conductive layer 8 may be made of an opaque metallic material.

In another embodiment of the present disclosure, as shown in FIG. 8B, the electronic device may simultaneously include the first line segment 41 shown in FIG. 7B and the groove G and the conductive layer 8 similar to those shown in FIG. 8A. In this way, the capacitive coupling effect caused between the signal line 3 and the data line 5 an be shielded.

In this embodiment, as shown in FIG. 8B, the insulating layer may include a second insulating layer 72, a third insulating layer 73 and a fourth insulating layer 74, and the groove G may be formed in the second insulating layer 72, the third insulating layer 73 and the fourth insulating layer 74 to enhance the shielding effect.

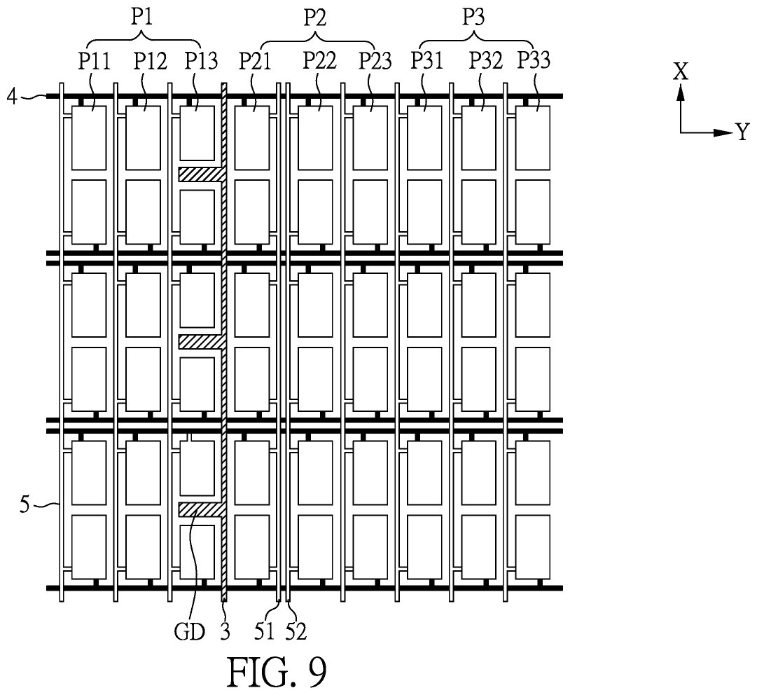

FIG. 9 is a top view of part of an active area of the electronic device according to an embodiment of the present disclosure, wherein FIG. 9 is similar to FIG. 4 except for the following differences. In addition, for convenience of description, the light shielding layer is omitted in FIG. 9.

As shown in FIG. 9, in the present disclosure, the gate lines 4 and the data lines 5 intersect to define a plurality of sub-pixel units, and the plurality of sub-pixel units may include a first sub-pixel unit P11, a second sub-pixel unit P12 and a third sub-pixel unit P13. The second sub-pixel unit P12 is disposed between the first sub-pixel unit P11 and the third sub-pixel unit P13. The first sub-pixel unit P11, the second sub-pixel unit P12 and the third sub-pixel unit P13 may firm a pixel unit P1. In the present disclosure, the electronic device may include a plurality of pixel units arranged in a matrix along the first direction X and the second direction Y, respectively, wherein the plurality of pixel units may include a first pixel unit P1, a second pixel unit P2 and the third pixel unit P3, the second pixel unit P2 is disposed between the first pixel unit P1 and the third pixel unit P3, and each pixel unit may include a plurality of sub-pixel units.

In the electronic device of FIG. 4, one of the signal lines 3 and one of the data lines 5 are disposed adjacent to each other, and the adjacent signal line 3 and data line 5 are disposed between two adjacent sub-pixel units. When using the same metal layer to form the signal line 3 and the data line 5, if the distance between the signal line 3 and the data line 5 is too small, the capacitive coupling effect between the signal line 3 and the data line 5 is likely to cause voltage transmission errors.

Therefore, as shown in FIG. 9, in one embodiment of the present disclosure, the data line 5 can be disposed on the side away from the signal line 3, and thus two data lines can be disposed between two adjacent sub-pixel units. More specifically, one of the signal lines 3 may be disposed between the third sub-pixel unit P13 of the first pixel unit P1 and the first sub-pixel unit P21 of the second pixel unit P2, and two data lines 51 and 52 of the data lines 5 may be disposed between the first sub-pixel unit P21 and the second sub-pixel unit P22 of the second pixel unit P2. Since the voltage difference between the two adjacent data lines 51 and 52 is smaller than the voltage difference between the adjacent data line 5 and signal line 3, it is able to reduce the capacitive coupling effect or improve the situation that the sub-pixel unit receives an erroneous signal voltage level.

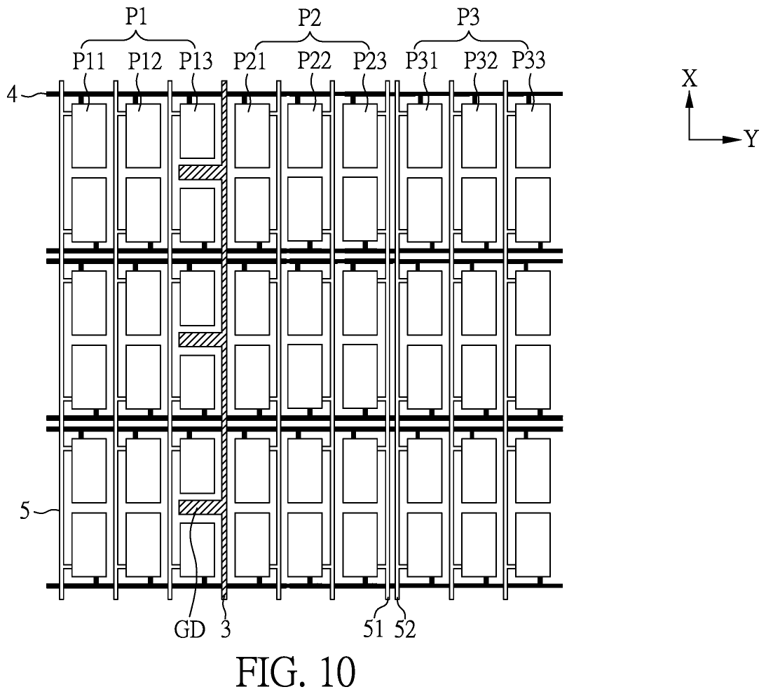

FIG. 10 is a top view of part of an active area of the electronic device according to an embodiment of the present disclosure, wherein FIG. 10 is similar to FIG. 9 except for the following differences.

In the electronic device of FIG. 9, the signal line 3 can be arranged between the adjacent first pixel unit P1 and second pixel unit P2, and the two adjacent data lines 51 and 52 can be arranged between the first sub-pixel unit P21 and the second sub-pixel unit P22 in the same pixel unit (for example, the second pixel unit P2). When two adjacent data lines 51 and 52 are disposed between two adjacent sub-pixel units in the same pixel unit, the light shielding layer BM disposed above the two adjacent data lines 51 and 52 has a larger width. Therefore, there will be a light shielding layer BM with a larger width in the same pixel unit.

Therefore, as shown in FIG. 10, in one embodiment of the present disclosure, the signal line 3 can be disposed between two adjacent pixel units, and the two adjacent data lines 51 and 52 can also be disposed between another two adjacent pixel units. More specifically, the signal line 3 may be arranged between the adjacent first pixel unit P1 and second pixel unit P2, and the two adjacent data lines 51 and 52 may be arranged between the second pixel unit P2 and the third pixel unit P3. In this way, the width of the light shielding layer BM between the sub-pixel units is kept substantially the same,

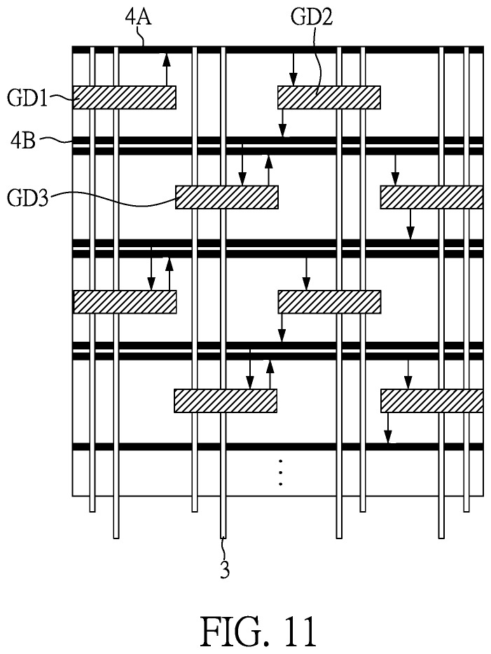

FIG. 11 is a schematic diagram of an active area of the electronic device according to an embodiment of the present disclosure. For the convenience of description, the data lines, the pixel units, and the light shielding layer disposed above the gate lines, the signal lines and the gate driving units are omitted in FIG. 11.

As shown in FIG. 11, in the present disclosure, the active area of the electronic device may include a plurality of gate driving units GD, and the plurality of gate driving units GD are electrically connected to the gate lines 4 through the signal lines 3, so as to transmit signals from the controller (not shown) to each gate driving unit GD to drive the entire electronic device. The circuit structure of each gate driving unit GD can be shown, for example, in FIG. 1, and spans a plurality of sub-pixel units as shown in FIG. 3B, while the details are not described herein again. In addition, the directions indicated by the arrows in FIG. 11 are the transmission directions of signals between a plurality of gate driving units GD. More specifically, the receiving switch element (not shown) of a gate driving unit GD1 may receive the first gate signal from a gate line and output the second gate signal to another gate line 4A through the buffer switch element (not shown) of the gate driving unit, and another gate driving unit GD2 may receive the second gate signal from another gate line 4A and output the third gate signal to the another gate line 4B for use as the input signal to the next-stage gate driving unit GD3, and so on. However, the electrical connection of each driving unit GD in the present disclosure is not limited thereto, and the arrangement positions of the plurality of gate driving units GD can be adjusted as needed while designing the electrical connection relationship and the signal transmission direction.

In the present disclosure, by arranging the gate driving units in the active area of the electronic device, the electronic device can be provided with the effect of a narrow border. In addition, the gate driving unit can be further arranged between the pixel units of the electronic device to improve the overall appearance of electronic device.

In the present disclosure, the electronic device may include a display panel, and the display panel may be, for example, a flexible display panel, a touch display panel, a curved display panel, or a tiled display panel, but the present disclosure is not limited thereto. Therefore, the electronic device of the present disclosure can be, for example, a monitor, a mobile phone, a notebook computer, a camcorder, a camera, a music player, a mobile navigation device, a TV, etc., which need to display images, but the present disclosure is not limited thereto. In some embodiments, the electronic device may include a sensing panel (for example, a fingerprint sensing panel), or an antenna device or the like.

The aforementioned specific embodiments should be construed as merely illustrative, and not limiting the rest of the present disclosure in any way.

What is claimed is:

1. An electronic device, comprising:
a substrate including an active area and a peripheral area adjacent to the active area;
a plurality of spacers disposed in the active area and including a first spacer and a second spacer;
a plurality of signal lines arranged on the substrate and extending along a first direction;
a plurality agate lines disposed on the substrate and extending along a second direction, wherein the first direction is different from the second direction; and
a gate driving unit disposed in the active area and including a receiving switch element and a buffer switch element,
wherein the receiving switch element is disposed corresponding to the first spacer and receives an input signal through one of the signal lines, and the buffer switch element is disposed corresponding to the second spacer and is electrically connected to the receiving switch element, wherein the buffer switch element outputs a scan signal to one of the gate lines.

2. The electronic device of claim 1, further comprising a plurality of data lines disposed on the substrate and extending along the first direction, wherein the gate lines and the data lines intersect to define a plurality of sub-pixel units, the sub-pixel units include a green sub-pixel unit and a blue sub-pixel unit, wherein an aperture ratio of the blue sub-pixel unit is different from that of the green sub-pixel unit.

3. The electronic device of claim 2, wherein a ratio of the aperture ratio of the blue sub-pixel unit to the aperture ratio of the green sub-pixel unit is between 70% and 99%.

4. The electronic device of claim 2, wherein at least one of the receiving switch element and the buffer switch element is disposed adjacent to the blue sub-pixel unit.

5. The electronic device of claim 1, wherein the gate driving unit further includes a switch element, and the switch element is electrically connected to at least one of the receiving switch element and the buffer switch element.

6. The electronic device of claim 1, wherein the buffer switch element includes a first sub-switch element and a second sub-switch element, wherein the first sub-switch element and the second sub-switch element are electrically connected to each other in parallel.

7. The electronic device of claim 1, further comprising a plurality of data lines disposed on the substrate and extending along the first direction, wherein, in the normal direction of the substrate, one of the signal lines at least partially overlaps one of the data lines.

8. The electronic device of claim 1, further comprising a plurality of data lines disposed on the substrate and extending along the first direction; and a first line segment disposed on the substrate and extending along the first direction, wherein one of the signal lines is disposed adjacent to one of the data lines, and the first line segment is disposed between the one of the signal lines and the one of the data lines.

9. The electronic device of claim 8, wherein the first line segment is electrically connected to one of the gate lines.

10. The electronic device of claim 1, further comprising a plurality of data lines disposed on the substrate and extending along the first direction; and a plurality of pixel units, the pixel units including a first pixel unit, a second pixel unit and a third pixel unit, wherein one of the signal lines is disposed between the first pixel unit and the second pixel unit, and two of the data lines are disposed between the second pixel unit and the third pixel unit.

11. The electronic device of claim 7, further comprising a touch signal line disposed on the substrate, wherein, in the normal direction of the substrate, the touch signal line at least partially overlaps the data line.

12. The electronic device of claim 9, further comprising an insulating layer disposed on the substrate, and located between the first line segment and the signal line and between the first line segment and the data line.

13. The electronic device of claim 12, further comprising a groove disposed between two adjacent signal line and data line, wherein the insulating layer has a multi-layer structure including a first insulating layer, a second insulating layer, a third insulating layer and a fourth insulating layer, and the groove is formed in the second insulating layer, the third insulating layer and the fourth insulating layer.

14. The electronic device of claim 13, wherein a conductive layer is disposed in the groove, and the conductive layer extends along the first direction and has a voltage level.

15. The electronic device of claim 14, wherein the conductive layer is disposed on the fourth insulating layer and extends in the groove.

16. The electronic device of claim 1, further comprising an insulating layer disposed on the substrate, and located between the first line segment and the signal line and between the first line segment and the data line 5.

17. The electronic device of claim 16, further comprising a groove disposed between two adjacent signal line and data line.

18. The electronic device of claim 17, wherein the insulating layer has a multi-layer structure including a first insulating layer, a second insulating layer, a third insulating layer and a fourth insulating layer, and the groove is formed in the first insulating layer, the second insulating layer, the third insulating layer and the fourth insulating layer.

19. The electronic device of claim 18, wherein a conductive layer is disposed in the groove, and the conductive layer is disposed on the fourth insulating layer and extends in the groove.

20. The electronic device of claim 1, further comprising a plurality of data lines disposed on the substrate and extending along the first direction; and a plurality of pixel units, the pixels units including a first pixel unit, a second pixel unit and a third pixel unit, each pixel unit including a first sub-pixel unit, a second sub-pixel unit and a third sub-pixel unit, wherein one of the signal lines is disposed between the third sub-pixel unit of the first pixel unit and the first sub-pixel unit of the second pixel unit, and two of the data lines are disposed between the first sub-pixel unit and the second sub-pixel unit of the second pixel unit.
